(19) United States
(12) Patent Application Publication
(10) Pub. No.: US 2017/0090650 A1
(43) Pub. Date: Mar. 30, 2017

(54) DISPLAY DEVICE

(71) Applicant: Samsung Display Co., Ltd., Yongin-Si (KR)

(72) Inventors: Ilwon JIN, Hwaseong-si (KR); Youngjun JEON, Cheonan-si (KR); Minseong SON, Asan-si (KR)

(21) Appl. No.: 15/150,776

(22) Filed: May 10, 2016

(30) Foreign Application Priority Data
Sep. 30, 2015 (KR) 10-2015-0138109

(51) Int. Cl. G06F 3/041; H05K 1/02

(52) U.S. Cl. CPC G06F 3/0416; H05K 1/0213; H05K 1/0296; H05K 1/028; H05K 2201/09218; G06F 2203/04102

(57) ABSTRACT

A display device includes a printed circuit board (“PCB”), a ground pad disposed on the PCB, a display panel including an upper substrate and a lower substrate, a touch sensor including a touch pattern directly disposed on an upper surface of the upper substrate, a main flexible PCB including a touch line which connects the upper substrate and the PCB to each other to transmit a touch signal generated from the touch sensor to the PCB, an upper ground pattern disposed on the upper substrate, and an upper ground line which connects the upper ground pattern and the ground pad to each other through the main flexible PCB.

This application claims priority to Korean Patent Application No. 10-2015-0138109, filed on Sep. 30, 2015, and all the benefits accruing therefrom under 35 U.S.C. §119, the content of which in its entirety is herein incorporated by reference.

### BACKGROUND

1. Field

Exemplary embodiments of the invention herein relate to a display device, and more particularly, to a display device having an electrostatic discharge function.

2. Description of the Related Art

Various types of display devices are developed for multimedia devices such as TVs, mobiles, navigations, computer monitors, game devices and the like.

Such display devices generally include a display panel which displays an image and a control unit which generates various signals to drive the display panel. The control unit may be implemented by various circuits and electronic devices disposed on a printed circuit board.

### SUMMARY

Exemplary embodiments of the invention provide a display device having an electrostatic discharge function.

An exemplary embodiment of the invention provides a display device including a printed circuit board (“PCB”), a ground pad disposed on the PCB, a display panel including an upper substrate and a lower substrate, a touch sensor including a touch pattern directly disposed on the upper substrate, a main flexible PCB which connects the upper substrate and the PCB to each other, the main flexible PCB including a touch line which transmits a touch signal generated in the touch sensor to the PCB, an upper ground pattern disposed on the upper substrate, and an upper ground line which connects the upper ground pattern and the ground pad to each other through the main flexible PCB.

In an exemplary embodiment, the upper ground pattern may be a line having a closed-loop shape to extend along an edge of the upper substrate.

In an exemplary embodiment, in a plan view, the upper ground pattern may surround the touch pattern.

In an exemplary embodiment, the upper ground pattern may be a pad having a circular or polygonal shape.

In an exemplary embodiment, the upper ground pattern may include a first sub-upper ground line disposed on the upper substrate, a second sub-upper ground line disposed on the main flexible PCB, and a third sub-upper ground line disposed on the PCB, wherein one end of the first sub-upper ground line is connected to the upper ground pattern, other side of the first sub-upper ground line is connected to one end of the second sub-ground line, other side of the second sub-upper ground line is connected to one end of the third sub-ground line, and other end of the third sub-ground line is connected to the ground pad.

In an exemplary embodiment, the display device may further include a lower ground pattern disposed on the lower substrate, a sub-flexible PCB which connects the lower substrate to the PCB, and a lower ground line which connects the lower ground pattern to the ground pad through the sub-flexible PCB.

In an exemplary embodiment, the lower ground line may include a first sub-lower ground line disposed on the lower substrate, a second sub-lower ground line disposed on the sub-flexible PCB, and a third sub-ground line disposed on the PCB, wherein one end of the first sub-lower ground line is connected to the lower ground pattern, other side of the first sub-lower ground line is connected to one end of the second sub-lower ground line, other end of the second sub-lower ground line is connected to one end of the third sub-lower ground line, and other end of the third sub-lower ground line is connected to the ground pad.

In an exemplary embodiment, the display device may further include a touch integrated circuit (“IC”) that is disposed (e.g., mounted) on the main flexible PCB to be connected with the touch line, the touch IC including a dummy input pin and a dummy output pin which are electrically connected to each other. The second sub-upper ground line includes a second-1 sub-upper ground line and a second-2 sub-upper ground line, wherein one end of the second-1 sub-upper ground line is connected to other end of the first sub-upper ground line, other end of the second-1 sub-upper ground line is connected to the dummy input pin, one end of the second-2 sub-upper ground line is connected to the dummy output pin, and other end of the second-2 sub-upper ground line is connected to one end of the third sub-upper ground line.

In an exemplary embodiment, the display device may further include a lower ground pattern disposed on the lower substrate and a lower ground line which connects the lower ground pattern and the upper ground pattern to each other through the main flexible PCB. The upper ground line includes a first sub-upper ground line disposed on the upper substrate, a second sub-upper ground line disposed on the main flexible PCB, and a third sub-upper ground line disposed on the PCB. The lower ground line includes a first sub-lower ground line disposed on the lower substrate and a second sub-lower ground line disposed on the main flexible PCB. One end of the first sub-upper ground line is connected to the upper ground pattern, other end of the first sub-upper ground line is connected to one end of the second sub-upper ground line, other end of the second sub-upper ground pattern is connected to one end of the third sub-ground line, other end of the third sub-upper ground line is connected to the ground pad, one end of the first sub-lower ground line is connected to the lower ground pattern, other end of the first sub-lower ground line is connected to one end of the second sub-lower ground line, and other end of the second sub-lower ground line is connected to the second sub-upper ground line.

In an exemplary embodiment, the display device further includes a lower ground pattern disposed on the lower substrate, and a lower ground line which connects the lower ground pattern and the ground pad to each other through the main flexible PCB. The upper ground line includes a first sub-upper ground line disposed on the upper substrate, a second sub-upper ground line disposed on the main flexible PCB, and a third sub-upper ground line disposed on the PCB, and the lower ground line includes a first-sub lower ground line disposed on the lower substrate, a second sub-lower ground line disposed on the main flexible PCB, and a third sub-ground line disposed on the PCB, wherein one end of the first sub-upper ground line is connected to the upper ground pattern, other end of the first sub-upper ground line is connected to one end of the second sub-upper ground line, other end of the second sub-upper ground line is connected to on end of the third sub-upper ground line, other end of the third sub-upper ground line is connected to the ground pad, one end of the first sub-lower ground line is connected to the lower ground pattern, other end of the first sub-lower ground line is connected o the one end of the second sub-upper ground line, of the end of the second sub-lower ground line is connected to one end of the third sub-lower ground line, and other end of the third sub-lower ground line is connected to the ground pad.

The upper ground pattern is disposed on the same layer on which the touch pattern is disposed, and includes the same material as the material of the ground pattern.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1 is a plan view of an exemplary embodiment of a display device according to the invention;

FIG. 2A is a cross-sectional view taken along line A-A′ illustrated in FIG. 1;

FIG. 2B is a cross-sectional view taken along line B-B′ illustrated in FIG. 1;

FIGS. 3A and 3B are views illustrating exemplary embodiments of upper ground patterns of display devices according to the invention;

FIG. 4 is a view illustrating another exemplary embodiment of a display device according to the invention;

FIG. 5 is a view illustrating another exemplary embodiment of a display device according to the invention; and

FIG. 6 is a view illustrating another exemplary embodiment of a display device according to the invention.

### DETAILED DESCRIPTION

Although specific embodiments are illustrated in the accompanying drawings and referenced in the specification, the invention can be modified in various manners and encompass embodiments not expressly disclosed. The scope of the exemplary embodiments of the invention are not limited to the specific embodiments and should be construed as including all the changes, equivalents, and substitutions that are within the spirit and scope of the system and method.

Like reference numerals in the drawings denote like elements. In the drawings, the dimensions of structures are exaggerated for clarity. Although terms like a first and a second are used to describe various elements, components, and/or sections in various embodiments of the invention, the elements, components, and/or sections are not limited thereto. These terms are used only to differentiate one element, component, or section from another one. Accordingly, it will be apparent that a first element, a first component, or a first section described hereinafter may refer to a second element, a second component, or a second section within the scope of technical idea of the invention. The terms of a singular form may include plural forms unless referred to the contrary.

The meaning of “include”, “comprise”, “including”, “comprising”, “have”, or “having” specifies a property, a fixed number, a step, a process, an element, a component and/or a combination thereof, but does not exclude other properties, fixed numbers, steps, processes, elements, components and/or combinations thereof. It will also be understood that when a layer, a film, a region, or a substrate is referred to as being “on” another one, it can be directly on the other one, or one or more intervening ones may also be present. To the contrary, when a layer, a film, a region, or a substrate is referred to as being “under” another one, it can be directly under the other one, or one or more intervening ones may also be present.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this invention will be thorough and complete, and will fully convey the scope of the invention to those skilled in the art. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. In an exemplary embodiment, when the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, when the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. In an exemplary embodiment, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, exemplary embodiments of the invention will be described in detail with reference to the accompanying drawings.

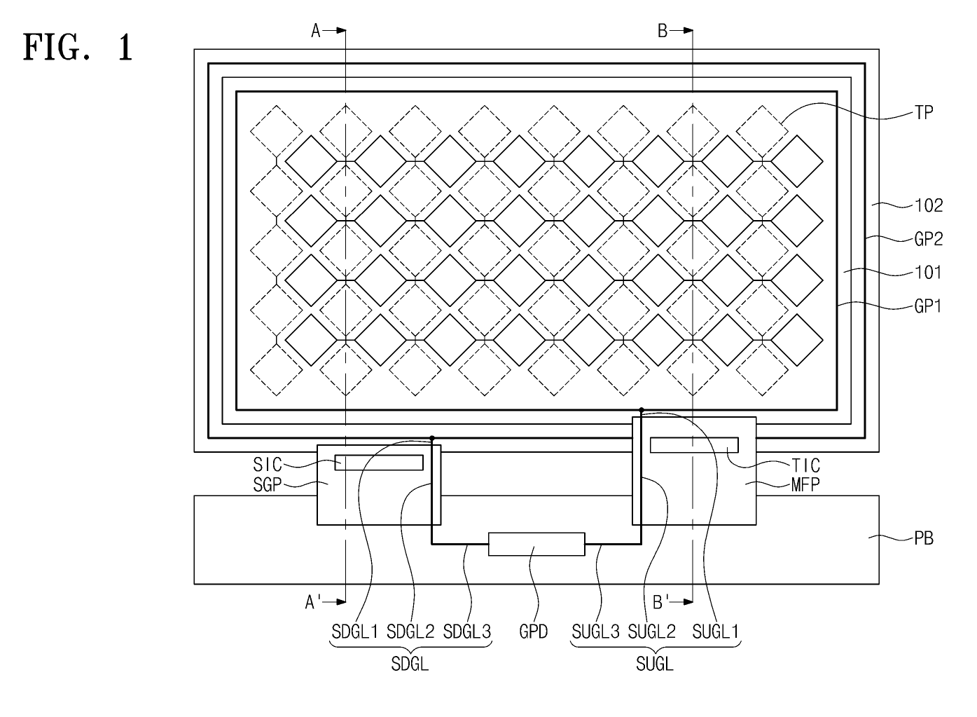

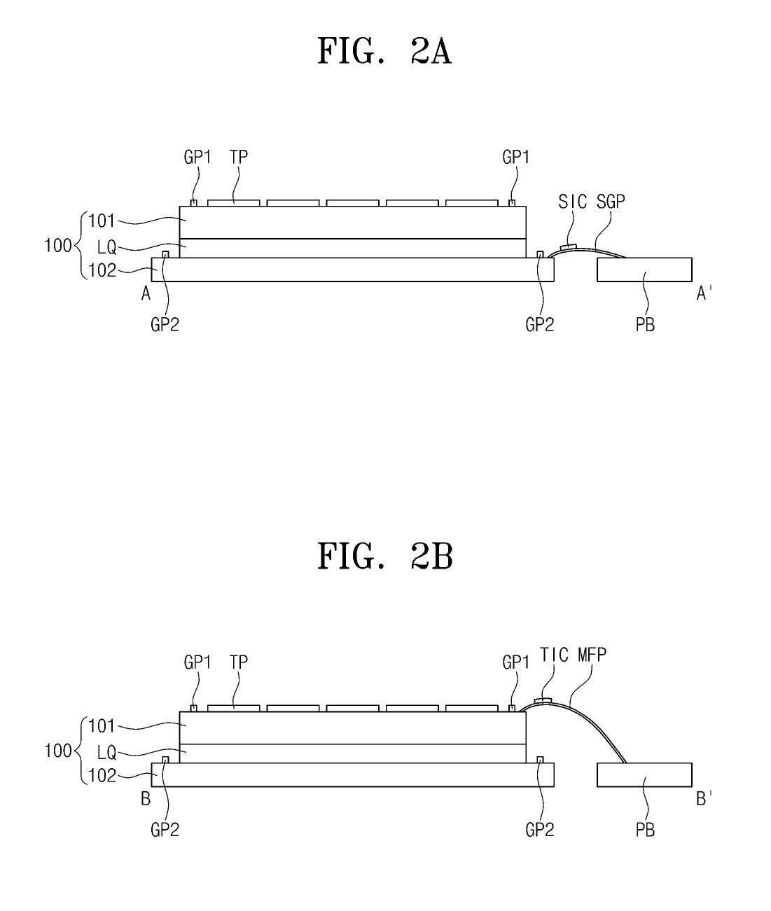

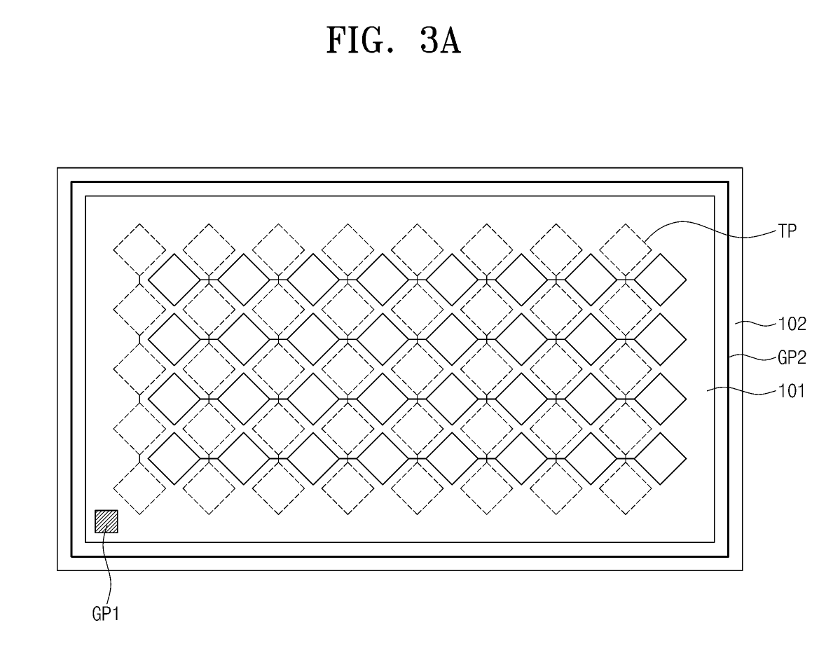

FIG. 1 is a plan view of a display device according to an exemplary embodiment of the invention, FIG. 2A is a cross-sectional view taken along line A-A′ illustrated in FIG. 1, and FIG. 2B is a cross-sectional view taken along B-B′ line illustrated in FIG. 1.

Referring to FIGS. 1, 2A and 2B, a display device according to an exemplary embodiment of the invention includes a printed circuit board (“PCB”) PB, a ground pad GPD, a display panel 100, a main flexible PCB MFP, a sub-flexible PCB SGP, a touch sensor, a touch integrated circuit TIC, an upper ground pattern GP1, a lower ground pattern GP2, an upper ground line SUGL, and a lower ground line SDGL.

The ground pad GPD is disposed on the PCB PB. The ground pad GPD may be disposed on an upper surface of the PCB PB. The ground pad GPD may include a ground electrode (not illustrated). Thus, the ground pad GPD may discharge static electricity applied to the ground pad GPD through the ground electrode.

Various types of display panels may be used for the display panel 100. In an exemplary embodiment of the invention, the display panel 100 may be an organic light emitting display panel (“OLED”), an electrophoretic display panel (“EPD”), or an electrowetting display panel (“EWD”). Hereinafter, it will be described as an example of the invention that a liquid crystal display (“LCD”) is used as the display panel 100.

According to an exemplary embodiment of the invention, the display device 100 may be provided in a rectangular plate shape having a pair of long sides and a pair of short sides. An output image may be displayed through the display panel 100.

The display panel 100 includes an upper substrate 101, a liquid crystal layer LQ, and a lower substrate 102.

The display panel 100 may include a plurality of pixels (not illustrated) arranged in a matrix form. Herein, each pixel may have several sub-pixels, and the respective sub-pixels may display colors which are different from each other. In an exemplary embodiment, each of the sub-pixels may display any one of red, green, or blue color, for example. Thus, light emitted from each of the sub-pixels may be any one of red, green, or blue color light.

Each of the sub-pixels may be electrically connected to a gate line and a data line, and be provided with a thin film transistor (“TFT”) (not illustrated) electrically connected to a corresponding pixel electrode of each pixel. The TFT may switch a driving signal provided to the corresponding pixel electrode.

A driver integrated circuit (“IC”) may be provided on one side of the lower substrate 102. The driver IC receives various signals to output a driving signal for driving the display panel 100 to the TFT in response to various control signals. The driver IC may include a source IC SIC which will be described later.

The upper substrate 101 may be provided with a color filter layer (not illustrated) which uses light supplied from a backlight unit (not illustrated) on the lower substrate 102 to generate a predetermined color, and a common electrode (not illustrated) disposed on the color filter layer to face the pixel electrode. Herein, the color filter layer may include a plurality of color filters having different colors, for example, red, green, and blue color. However, the invention is not limited thereto, and the color filter layer may include various other colors.

A touch sensor provided with a touch pattern TP may be disposed directly on a top surface of the upper substrate 101. In more detail, the touch sensor may be defined on the top surface of the upper substrate 101 through the on cell method.

According to an exemplary embodiment of the invention, the touch pattern TP may have a diamond shape. The touch pattern TP may be a transparent electrode. In an exemplary embodiment, the transparent electrode may include, for example, optically thin Li, Ca, LiF/Ca, LiF/Al, Al, Mg, BaF, Ba, Ag, or a compound or combination thereof (for example, a combination of Ag and Mg), or a transparent metallic oxide, for example, indium tin oxide (“ITO”), indium zinc oxide (“IZO”), zinc oxide (ZnO), or indium tin zinc oxide (“ITZO”). In an alternative exemplary embodiment, the touch pattern TP may include at least one of Mo and Ti, for example.

The touch pattern TP may include touch patterns arranged in a row direction and touch patterns arranged in a column direction. In an exemplary embodiment, first touch patterns arranged in the row direction and second touch patterns arranged in the column direction do not overlap each other, for example.

The touch pattern TP may sense an approach or contact of a portion of a human body or a conductive means. In more detail, the touch pattern TP may sense the approach or contact of the portion of human body or the contact means by using a method of detecting the magnitude of capacitance disposed between the touch pattern TP and the portion of human body.

An upper ground pattern GP1 may be disposed on the upper substrate 101. In an exemplary embodiment, the upper ground pattern GP1 may be a line having a closed-loop shape to extend along a periphery of the upper substrate 101 as illustrated in FIG. 1, for example. In more detail, in a plan view of the upper substrate 101, the upper ground pattern GP1 may be disposed in a shape which surrounds the touch pattern TP.

Although not illustrated in FIGS. 2A and 2B, according to an exemplary embodiment of the invention, the upper ground pattern GP1 may be disposed on the same layer on which the touch pattern TP is disposed. The touch pattern TP may include the same material as that of the upper ground pattern GP1. In an exemplary embodiment, the upper touch pattern TP may be a transparent electrode including a transparent material, and the upper ground pattern GP1 may also be a transparent electrode including a transparent material like the touch pattern TP, for example.

The upper ground pattern GP1 may absorb static electricity generated in the upper substrate 101. The absorbed static electricity may be transmitted to the ground pad GPD through the upper ground line SUGL which will be described later. The transmitted static electricity may be discharged by the ground pad GPD as previously described.

The lower ground pattern GP2 may be disposed on the lower substrate 102. The lower ground pattern GP2 may be disposed on a top surface of the lower substrate 102 and have the same shape as that of the upper ground pattern GP1.

The lower ground pattern GP2 may absorb static electricity generated in the lower substrate 102. The absorbed static electricity may be transmitted to the ground pad GPD through the lower ground line SDGL which will be described later. The transmitted static electricity may be discharged by the ground pad GPD as previously described.

The liquid crystal layer LQ may be disposed between the upper substrate 101 and the lower substrate 102.

Liquid crystal molecules of the liquid crystal layer LQ are arranged in a specific direction by a voltage applied to the pixel electrode and the common electrode to adjust the transmittance of light supplied from the backlight unit so that the display panel 100 may display an image.

Although not illustrated in drawings, a sealant (not illustrated) for protecting the liquid crystal layer LQ may be provided along edges of the liquid crystal layer LQ. The sealant may prevent liquid crystal in the liquid crystal layer LQ from leaking to the outside.

The main flexible PCB MFP may connect the upper substrate 101 and the PCB FB to each other. The touch IC TIC may be disposed on the main flexible PCB MFP. In an exemplary embodiment, the touch IC TIC may receive a touch signal generated in the touch sensor through a touch line (not illustrated) that is connected to the touch pattern TP, for example.

The sub-flexible PCB SGP may connect the upper substrate 102 and the PCB PB to each other. The source IC SIC may be disposed on the sub-flexible PCB SGP.

Referring to FIG. 1, the upper ground line SUGL may include a first sub-upper ground line SUDL1, a second sub-upper ground line SUGL2, and a third sub-upper ground line SUGL3.

The first sub-upper ground line SUGL1 may be, for example, disposed on the top surface of the upper substrate 101. According to an exemplary embodiment of the invention, the first sub-upper ground line SUGL1 may also be disposed on a bottom surface of the upper substrate 101.

The second sub-upper ground line SUGL2 may be disposed on the main flexible PCB MFP. The third sub-upper ground line SUGL3 may be disposed on the PCB PB.

In an exemplary embodiment, one end of the first sub-upper ground line SUGL1 is connected to the upper ground pattern GP1, and the other end of the first sub-upper ground line SUGL1 may be connected to one end of the second sub-upper ground line SUGL2, for example. The other end of the second sub-upper ground line SUGL2 is connected to one end of the third sub-upper ground line SUGL3, and the other end of the third sub-upper ground line SUGL3 may be connected to the ground pad GPD.

Thus, the first sub-upper ground line SUGL1 may be directly connected to the second sub-upper ground line SUGL2. The second sub-upper ground line SUGL2 is directly connected to the third sub-upper ground line SUGL3 to allow the upper ground pattern GP1 and the ground pad GPD to be electrically connected to each other.

The lower ground line SDGL may include a first sub-lower ground line SDGL1, a second sub-lower ground line SDGL2, and a third sub-lower ground line SDGL3.

The first sub-lower ground line SDGL1 may be, for example, disposed on the top surface of the lower substrate 102. According to an exemplary embodiment of the invention, the first sub-lower ground line SDGL1 may be disposed on a bottom surface of the lower substrate 102.

The second sub-lower ground line SDGL2 may be disposed on the sub-flexible PCB SGP. The third sub-lower ground line SDGL3 may be disposed on the PCB PB.

In an exemplary embodiment, one end of the first sub-lower ground line SDGL1 is connected to the lower ground pattern GP2, and the other end other the first sub-lower ground line SDGL1 may be connected to one end of the second sub-lower ground line SDGL2, for example. The other end of the second sub-lower ground line SDGL2 is connected to one end of the third sub-lower ground line SDGL3, and the other end of the third sub-lower ground line SDGL3 may be connected to the ground pad GPD.

Thus, the first sub-lower ground line SDGL1 may be directly connected to the second sub-lower ground line SDGL2. The second sub-lower ground line SDGL2 is directly connected to the third sub-lower ground line SDGL3 to allow the lower ground pattern GP2 and the ground pad GPD to be electrically connected to each other.

The upper ground pattern GP1 of the upper substrate 101 may absorb static electricity generated in the upper substrate 101 to transmit the absorbed static electricity to the first sub-upper ground line SUGL1. The first sub-upper ground line SUGL1 may transmit the static electric to the second sub-upper ground line SUGL2. The second sub-upper ground line SUGL2 may transmit the static electricity to the third sub-upper ground line SUGL3. The third sub-upper ground line SUGL3 may transmit the static electricity to the ground pad GPD. Also, the ground pad GPD discharges the applied static electricity so that the display panel 100 may be prevented from being damaged by the static electricity generated in the upper substrate 101.

In the same manner, the lower ground pattern GP2 of the lower substrate 102 may absorb static electricity generated in the lower substrate to transmit the generated static electricity to the first sub-lower ground line SDGL1. The first sub-lower ground line SDGL1 may transmit the static electricity to the second sub-lower ground line SDGL2. The second sub-lower ground line SDGL2 may transmit the static electricity to the third sub-lower ground line SDGL3. The third sub-lower ground line SDGL3 may transmit the static electricity to the ground pad GPD. Also, the ground pad GPD discharges the applied static electricity so that the display panel 100 may be prevented from being damaged by the static electricity generated in the lower substrate 102.

Consequently, according to a display device according to an exemplary embodiment of the invention, static electricity introduced into the display panel 100 from the outside is not discharged by a method in which the upper substrate and the lower substrate, which are insulated from each other, are electrically connected to each other by a conductive tape, a conductive member, a silver dot, or the like and a circuit board connected to the lower substrate 102 is used, but is discharged by the main flexible PCB MFP on which the touch IC TIC is disposed and the sub-flexible PCB SGP on which the source IC SIC is disposed without using materials such as a conductive tape, a conductive member, a silver dot, or the like, so that an effect of time and cost saving in manufacturing process of the display device may be realized.

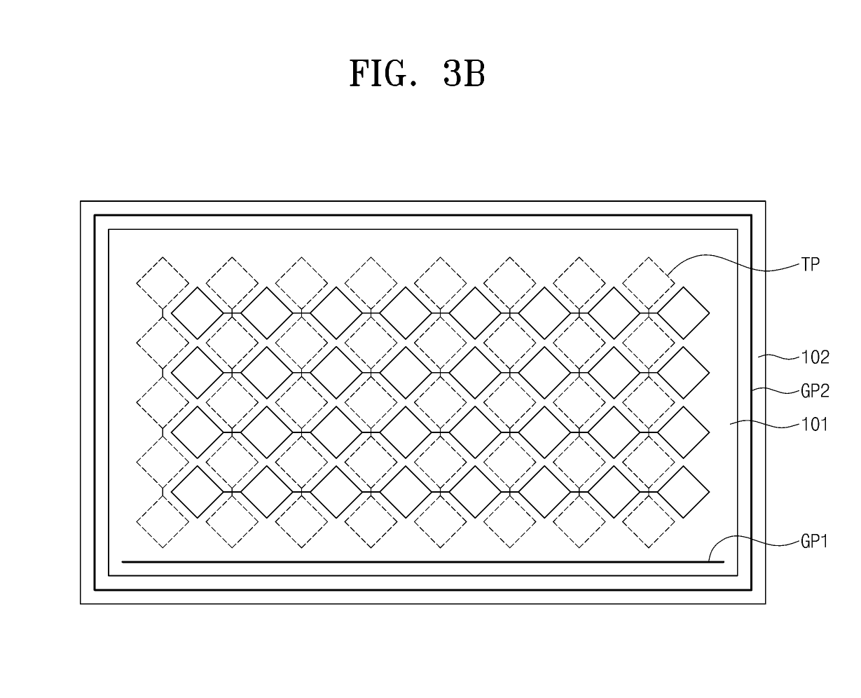

FIGS. 3A and 3B are views exemplarily illustrating upper ground patterns of display devices according to exemplary embodiments of the invention.

Referring to FIG. 3A, an upper ground pattern GP1 may be a pad having a quadrangular shape. In an exemplary embodiment, the upper ground pattern GP1 may be a pad including a metallic material, for example. The upper ground pattern GP1 illustrated in FIG. 3A may introduce static electricity from the outside of the upper substrate 101 to transmit the introduced static electricity to the first sub-upper ground line SUGL1 in the same manner as the upper ground pattern GP1 illustrated in FIG. 1.

Although the ground pattern GP1 having a quadrangular shape is illustrated in FIG. 3A, the invention is not limited thereto. In another exemplary embodiment, the upper ground pattern GP1 may be a pad having various other shapes such as a circular or polygonal shape.

Referring to FIG. 3B, the upper ground pattern GP1 may be disposed adjacent to any one of edges of the upper substrate 101. In FIG. 3B, the ground pattern GP1 is illustrated to be adjacent to a lower edge of the upper substrate 101.

The upper ground pattern GP1 may be a linear metallic conductive line as illustrated in FIG. 3B.

As described above, the upper ground pattern GP1 may introduce static electricity from the outside of the upper substrate 101 to transmit the introduced static electricity to the first sub-upper ground line SUGL1.

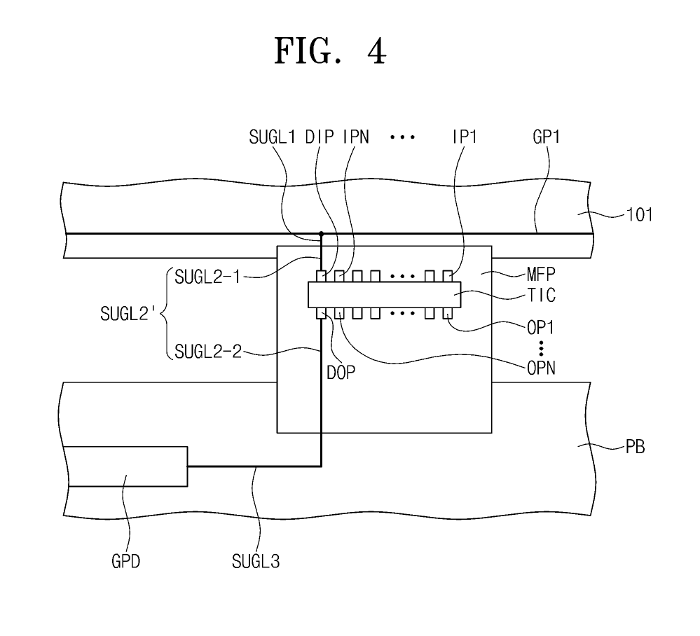

FIG. 4 is a view illustrating a display device according to another exemplary embodiment of the invention.

Referring to FIG. 4, a touch IC TIC may include first to Nth input pins IP1 to IPN, first to Nth output pins OP1 to OPN, a dummy input pin DIP, a dummy output pin DOP, and an internal circuit (not illustrated).

The first to Nth input pins IP1 to IPN may be respectively connected to first to Nth output pins OP1 to OPN through the internal circuit. In more detail, although an inner wiring structure of the touch IC TIC is omitted from the FIG. 4, the first to Nth input pins IP1 to IPN may be electrically connected to the first to Nth output pins OP1 to OPN, respectively.

Each of the first to Nth input pins IP1 to IPN may be connected to the touch lines. In an exemplary embodiment, the touch pattern TP (refer to FIGS. 1 to 3B) may output the touch signal, which is an electric signal, by approach or contact of a portion of a human body or a conductive touch means, for example.

The dummy input pin DIP and the dummy output pin DOP may be electrically connected to each other.

The display device illustrated in FIG. 4 is different from the display device illustrated in FIGS. 1, 2A and 2B in that the second sub-upper ground pattern SUGL2′ may include a second-1 sub-upper ground line SUGL2-1 and a second-2 sub-upper ground line SUGL2-2. One end of the second-1 sub-upper ground line SUGL2-1 may be connected to the other end of the first sub-upper ground line SUGL1 which is described in FIG. 1. The other end of the second-1 sub-upper ground line SUGL2-1 may be connected to the dummy input pin DIP.

One end of the second-2 sub-upper ground line SUGL2-2 may be connected to the dummy output pin DOP. The other end of the second-2 sub-upper ground line SUGL2-2 may be connected to one end of the third sub-upper ground line SUGL3 which is described in FIG. 1.

A difference between the display device in FIG. 4 and the display device in FIGS. 1, 2A and 2B is as follows.

The display device in FIG. 4 connects the first sub-upper ground line SUGL1 and the third sub-upper ground line SUGL3 to each other using the touch IC TIC, while the display device in FIGS. 1, 2A and 2B connects the first sub-upper ground line SUGL1 and the third sub-upper ground line SUGL3 to each other using the second sub-upper ground line SUGL2 only without using the touch IC on the main flexible PCB.

A time saving effect in the manufacturing process may be realized by utilizing an input pin and an output pin of the touch IC as a ground line as illustrated in FIG. 4.

Since the remaining constituents disclosed in FIG. 4 are the same as those described in FIGS. 1, 2A and 2B, a description thereof is omitted.

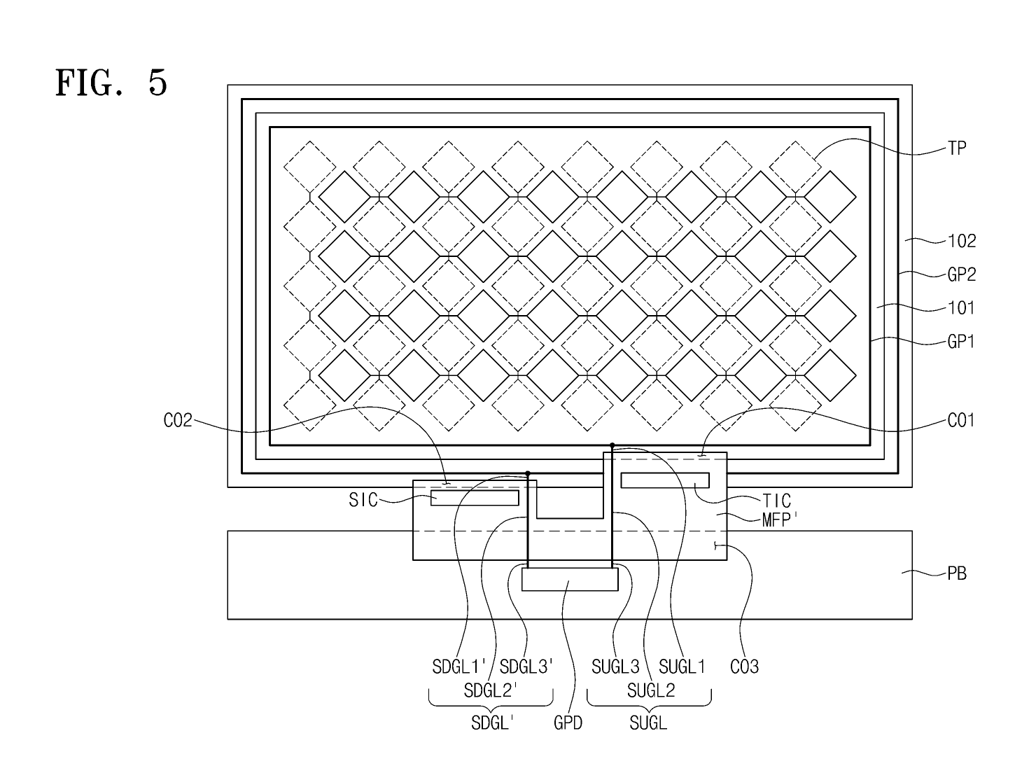

FIG. 5 is a view illustrating a display device in another exemplary embodiment of the invention.

Referring to FIG. 5, a display device in FIG. 5 is different from a display device in FIGS. 1, 2A and 2B in that the sub-flexible PCB SGP in FIGS. 1 and 2A is removed, a main flexible PCB MFP′ connects an upper substrate 101 to a PCB PB, and may connect a lower substrate 102 to the PCB PB at the same time.

In more detail, the main flexible PCB MFP′ may include a first connection unit CO1, a second connection unit CO2, and a third connection unit CO3.

The first connection unit CO1 may be a portion of the main flexible PCB MFP′ overlapping the upper substrate 101 as illustrated in FIG. 5, the second connection unit CO2 may be a portion of the main flexible PCB MFP′ overlapping the lower substrate 102, and the third connection unit CO3 may be a portion of the main flexible PCB MFP′ overlapping the PCB PB.

Since the connection of an upper ground line SUGL is described in FIG. 1, a description thereof is omitted.

A lower ground line SDGL′ includes a first sub-lower ground line SDGL1′ disposed on the lower substrate 102, a second sub-lower ground line SDGL2′ disposed on the main flexible PCB MFP′, and a third sub-lower ground line SDGL3′ disposed on the PCB PB.

One end of the first sub-lower ground line SDGL1′ may be connected to the lower ground pattern GP2, and the other end of the first sub-lower ground line SDGL1′ may be connected to one end of the second sub-lower ground line SDGL2′.

The other end of the second sub-lower ground line SDGL2′ may be connected to one end of the third sub-lower ground line SDGL3′, and the other end of the third sub-lower ground line SDGL3′ may be connected to the ground pad GPD. Summarizing, FIG. 5 is different from FIG. 2 in that the upper substrate 101 and the lower substrate 102 are simultaneously connected to the PCB PB by one flexible PCB not by one pair of flexible PCB s so that static electricity introduced from the outside of the upper and lower substrates 101 and 102 is transmitted to the ground pad GPD.

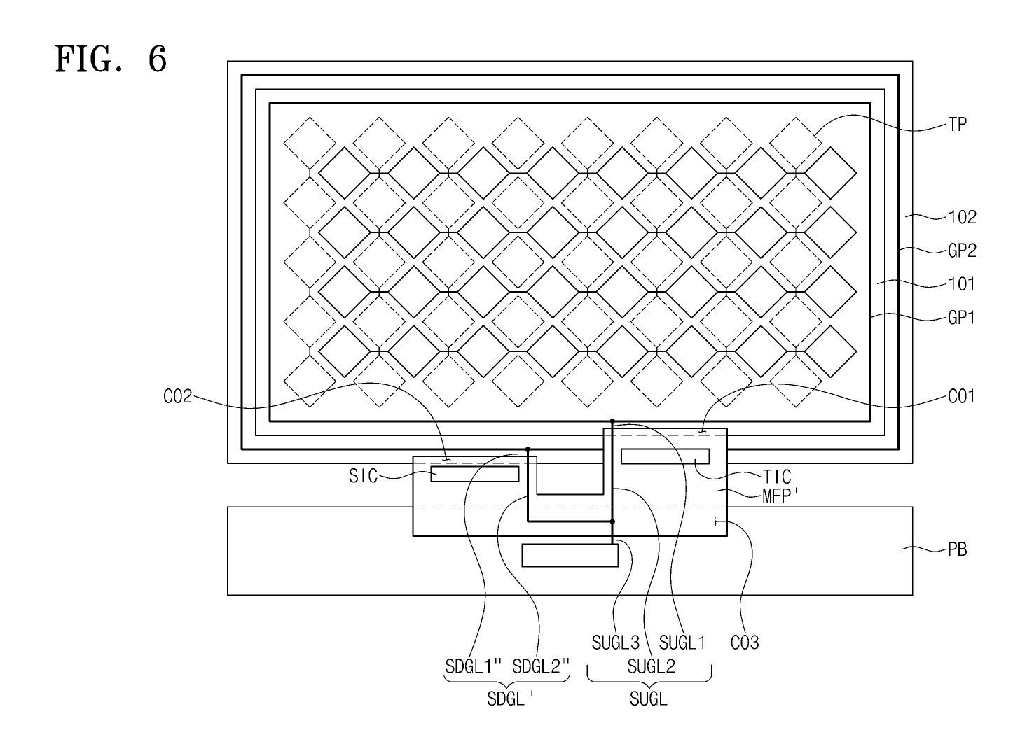

FIG. 6 is a view illustrating a display device according to another exemplary embodiment of the invention.

Referring to FIG. 6, the sub-flexible PCB SGP illustrated in FIGS. 1 and 2A is removed from a display device in FIG. 6 as in FIG. 5, and a main flexible PCB MFP′ connects an upper substrate 101 and a PCB PB to each other, and may simultaneously connect a lower substrate 102 and the PCB PB to each other.

Since the connection of an upper ground line SUGL is described in FIG. 1, a description thereof is omitted.

A lower ground line SDGL″ may include a first sub-lower ground line SDGL1″ disposed on the lower substrate 102 and a second sub-lower ground line SDGL2″ disposed on the main flexible PCB MFP′.

One end of the first sub-lower ground line SDGL1″ may be connected to a lower ground pattern GP2, and the other end of the first sub-lower ground line SDGL1″ may be connected to one end of the second sub-lower ground line SDGL2″. The other end of the second sub-lower ground line SDGL2″ may be connected to the second sub-upper ground line.

Summarizing, in the display device in FIG. 6 unlike the display device in FIG. 5, the second sub-lower ground line SDGL2″ is directly connected to the second sub-upper ground line SUGL2 on the main flexible PCB MFP′, the second sub-upper ground line SUGL2 is connected to one end of the third sub-upper ground line SUGL3, and the other end of the third sub-upper ground line SUGL3 may be connected to the ground pad GPD. Thus, the static electricity introduced from the outside of the upper substrate 101 and the static electricity introduced from the outside of the lower substrate 102 are combined at a junction point at which the second sub-upper ground line SUGL2 meets the second sub-lower ground line SDGL2″, so that the static electricity may be transmitted to the ground pad GPD.

According to a display device according to an exemplary embodiment of the invention, static electricity introduced into a display panel from the outside is not discharged by a method in which an upper substrate and a lower substrate, which are insulated from each other, are electrically connected to each other by a conductive tape, a conductive member, a silver dot, or the like and a circuit board connected to the lower substrate is used, but is discharged by a main flexible PCB on which a touch IC is disposed and a sub-flexible PCB on which a source IC SIC is disposed without using materials such as a conductive tape, a conductive member, a silver dot, or the like, so that an effect of time and cost saving in manufacturing process of the display device may be realized.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A display device comprising:
a printed circuit board;
a ground pad disposed on the printed circuit board;
a display panel including an upper substrate and a lower substrate;
a touch sensor including a touch pattern directly disposed on a top surface of the upper substrate;
a main flexible printed circuit board including a touch line which connects the upper substrate and the printed circuit board to each other and transmits, to the printed circuit board, a touch signal generated from the touch sensor;
an upper ground pattern disposed on the upper substrate; and
an upper ground line which connects the upper ground pattern and the ground pad to each other through the main flexible printed circuit board.

2. The display device of claim 1, wherein the upper ground pattern is a line having a closed-loop shape and extending along an edge of the upper substrate.

3. The display device of claim 2, wherein the upper ground pattern surrounds the touch pattern in a plan view.

4. The display device of claim 1, wherein the upper ground pattern is a pad having one of a circular shape and a polygonal shape.

5. The display device of claim 1, wherein the upper ground line comprises:
a first sub-upper ground line disposed on the upper substrate;
a second sub-upper ground line disposed on the main flexible printed circuit board; and
a third sub-upper ground line disposed on the printed circuit board,
wherein one end of the first sub-upper ground line is connected to the upper ground pattern and the other end of the first sub-upper ground line is connected to one end of the second sub-upper ground line;
the other end of the second sub-upper ground line is connected to one end of the third sub-upper ground line; and
the other end of the third sub-upper ground line is connected to the ground pad.

6. The display device of claim 5, further comprising:
a lower ground pattern disposed on the lower substrate;
a sub-flexible printed circuit board which connects the lower substrate and the printed circuit board to each other; and
a lower ground line which connects the lower ground pattern and the ground pad to each other through the sub-flexible printed circuit board.

7. The display device of claim 6, wherein the lower ground line comprises:
a first sub-lower ground line disposed on the lower substrate;
a second sub-lower ground line disposed on the sub-flexible printed circuit board; and
a third sub-lower ground line disposed on the printed circuit board,
wherein one end of the first sub-lower ground line is connected to the lower ground pattern and the other end of the first sub-lower ground line is connected to one end of the second sub-lower ground line; and
the other end of the second sub-lower ground line is connected to one end of the third sub-lower ground line and the other end of the third sub-lower ground line is connected to the ground pad.

8. The display device of claim 5, further comprising a touch integrated circuit disposed on the main flexible printed circuit board and connected to the touch line,
wherein the touch integrated circuit includes a dummy input pin and a dummy out pin which are electrically connected to each other,
the second sub-upper ground line includes a second-1 sub-upper ground line and a second-2 sub-upper ground line,
wherein one end of the second-1 sub-upper ground line is connected to the other end of the first sub-upper ground line, and the other end of the second-1 sub-upper ground line is connected to the dummy input pin, and
one end of the second-2 sub upper ground line is connected to an upper dummy output pin, and the other end of the second-2 sub-upper ground line is connected to one end of the third sub-upper ground line.

9. The display device of claim 1, further comprising:
a lower ground pattern disposed on the lower substrate; and
a lower ground line which connects the lower ground pattern and the ground pad to each other through the main flexible printed circuit board,
wherein the upper ground line includes:
a first sub-upper ground line disposed on the upper substrate;
a second sub-upper ground line disposed on the main flexible printed circuit board; and
a third sub-upper ground line disposed on the printed circuit board, and
the lower ground line includes:
a first sub-lower ground line disposed on the lower substrate; and
a second sub-lower ground line disposed on the main flexible printed circuit board,
wherein one end of the first sub-upper ground line is connected to the upper ground pattern and the other end of the first sub-upper ground line is connected to one end of the second sub-upper ground line;
the other end of the second sub-upper ground line is connected to one end of the third sub-upper ground line;
the other end of the third sub-upper ground line is connected to the ground pad;
one end of the first sub-lower ground line is connected to the lower ground pattern and the other end of the first sub-lower ground line is connected to one end of the second sub-lower ground line; and
the other end of the second sub-lower ground line is connected to the second sub-upper ground line.

10. The display device of claim 1, further comprising:
a lower ground pattern disposed on the lower substrate; and
a lower ground line which connects the lower ground pattern and the ground pad to each other through the main flexible printed circuit board,
wherein the upper ground line includes:
a first sub-upper ground line disposed on the upper substrate;
a second sub-upper ground line disposed on the main flexible printed circuit board; and
a third sub-upper ground line disposed on the printed circuit board, and
the lower ground line includes:
a first sub-lower ground line disposed on the lower substrate;
a second sub-lower ground line disposed on the main flexible printed circuit board; and
a third sub-lower ground line disposed on the printed circuit board,
wherein one end of the first sub-upper ground line is connected to the upper ground pattern and the other end of the first sub-upper ground pattern is connected to one end of the second sub-upper ground line;
the other end of the second sub-upper ground line is connected to one end of the third sub-upper ground line and the other end of the third sub-upper ground line is connected to the ground pad;
one end of the first sub-lower ground line is connected the lower ground pattern and the other end of the first sub-lower ground line is connected to one end of the second sub-lower ground line; and
the other end of the second sub-lower ground line is connected to one end of the third sub-lower ground line and the other end of the third sub-lower ground line is connected to the ground pad.

11. The display device of claim 1, wherein the upper ground pattern is disposed on the same layer on which the touch pattern is disposed, and comprises the same material as that of the touch pattern.
